(19) United States
(12) Patent Application Publication
(10) Pub. No.: US 2015/0228840 A1
(43) Pub. Date: Aug. 13, 2015

(54) PHOTOCONDUCTIVE ANTENNA, CAMERA, IMAGING DEVICE, AND MEASUREMENT DEVICE

(71) Applicant: SEIKO EPSON CORPORATION, Tokyo (JP)

(72) Inventor: Satoshi TAKENAKA, Chino-shi (JP)

(21) Appl. No.: 14/615,216

(22) Filed: Feb. 5, 2015

(30) Foreign Application Priority Data
Feb. 7, 2014 (JP) 2014-022242

(51) Int. Cl. H01L 31/16; G01N 21/3581

(52) U.S. Cl. CPC H01L 31/16; G01N 21/3581; G01N 2201/06113; G01N 2201/0697

(57) ABSTRACT

A photoconductive antenna that generates a terahertz wave by irradiation with a light pulse, includes: a carrier generation layer that has carriers formed therein by irradiation with the light pulse; and a first electrode and a second electrode, located above the carrier generation layer, which apply a voltage to the carrier generation layer, wherein the carrier generation layer includes a protruding portion which is irradiated with the light pulse.

### BACKGROUND

1. Technical Field

The present invention relates to a photoconductive antenna, a camera, an imaging device, and a measurement device.

2. Related Art

In recent years, terahertz waves which are electromagnetic waves having a frequency equal to or greater than 100 GHz and equal to or less than 30 THz have attracted attention. The terahertz waves can be used in, for example, various types of measurement such as imaging and spectroscopic measurement, non-destructive tests, and the like.

Terahertz wave generation devices that generate such terahertz waves include, for example, a light pulse generation device that generates a light pulse having a pulse width of approximately subpicoseconds (several hundred femtoseconds), and a photoconductive antenna that generates a terahertz wave by irradiation with the light pulse generated in the light pulse generation device.

For example, JP-A-2009-124437 discloses a photoconductive antenna including a semi-insulating GaAs substrate, a GaAs (LT-GaAs) layer formed on the semi-insulating GaAs substrate by a low-temperature MBE (molecular beam epitaxy) method, and a pair of electrodes formed on the upper surface of the LT-GaAs layer. Further, JP-A-2009-124437 discloses that free carriers excited in the LT-GaAs layer are accelerated by an electric field caused by a bias voltage, whereby a current flows, and a terahertz wave is generated due to a change in this current.

However, in the photoconductive antenna disclosed in JP-A-2009-124437, since the LT-GaAs layer (carrier generation layer) has a flat layer structure, a terahertz wave generated between a pair of electrodes by irradiation with a pulsed light is emanated, for example, from the upper surface of the LT-GaAs layer which is irradiated with the light pulse to the semi-insulating GaAs substrate. For this reason, depending on the arrangement position of a post-stage optical system (for example, a lens), a portion of the terahertz wave generated from the photoconductive antenna is not able to be incident on the optical system, and thus utilization efficiency may be reduced.

### SUMMARY

An advantage of some aspects of the invention is to provide a photoconductive antenna which is capable of increasing utilization efficiency. Another advantage of some aspects of the invention is to provide a camera, an imaging device, and a measurement device which include the aforementioned photoconductive antenna.

An aspect of the invention is directed to a photoconductive antenna that generates a terahertz wave by irradiation with a light pulse, including: a carrier generation layer that has carriers formed therein by irradiation with the light pulse; and a first electrode and a second electrode, located above the carrier generation layer, which apply a voltage to the carrier generation layer, wherein the carrier generation layer includes a protruding portion which is irradiated with the light pulse.

In such a photoconductive antenna, the terahertz wave which is generated in the protruding portion is reflected from the lateral side of the protruding portion, and then can be emitted to the outside. Therefore, the terahertz wave which is generated in the protruding portion is not emanated until the terahertz wave reaches the lateral side of the protruding portion and then comes out of the protruding portion. Thus, in such a photoconductive antenna, it is possible to reduce an area in which the terahertz wave is distributed, and to increase the utilization efficiency of light.

Meanwhile, in the disclosure according to the invention, when the wording “above” is used in, for example, the phrase “form another specific thing (hereinafter, referred to as “B”) “above” a specific thing (hereinafter, referred to as “An)” or the like, a case where B is formed directly on A and a case where B is formed on A through another thing are assumed to be included, and the wording “above” is used.

In the photoconductive antenna according to the aspect of the invention, the first electrode and the second electrode may be located above the protruding portion.

In such a photoconductive antenna, a distance between the first electrode and the second electrode is smallest in the upper surface of the protruding portion. For this reason, in such a photoconductive antenna, an electric field intensity in the vicinity of the upper surface becomes largest in the depth direction of the protruding portion, and the traveling speed of carriers traveling along the vicinity of the upper surface becomes higher. Therefore, in such a photoconductive antenna, it is possible to generate a terahertz wave efficiently (the detailed description thereof will be given later).

In the photoconductive antenna according to the aspect of the invention, the first electrode and the second electrode may be provided on a lateral side of the protruding portion.

In such a photoconductive antenna, it is possible to reflect a terahertz wave, from, for example, the interface between the protruding portion and the first electrode and the interface between the protruding portion and the second electrode.

The photoconductive antenna according to the aspect of the invention may include an insulating layer which is provided on the lateral side of the protruding portion.

In such a photoconductive antenna, the first electrode and the second electrode can be formed in a shape which has a small stepped difference. Thereby, in such a photoconductive antenna, it is possible to prevent the first electrode and the second electrode from being disconnected from each other.

In the photoconductive antenna according to the aspect of the invention, the insulating layer may be provided on an upper surface of the protruding portion.

In such a photoconductive antenna, it is possible to suppress a flow of a leakage current between the first electrode and the second electrode, and to improve a breakdown voltage.

In the photoconductive antenna according to the aspect of the invention, the planar shape of the protruding portion may be circular.

In such a photoconductive antenna, for example, the cross-sectional shape of the terahertz wave which is emitted from the photoconductive antenna can be formed to be circular. Thereby, it is possible to facilitate the design of a post-stage optical system (lens).

In the photoconductive antenna according to the aspect of the invention, the carrier generation layer may be formed of a semi-insulating layer substrate.

In such a photoconductive antenna, the carrier generation layer can have higher carrier mobility than in a case where the layer is formed of an LT-GaAs layer.

Another aspect of the invention is directed to a terahertz wave generation device including: a light pulse generation device that generates a light pulse; and the photoconductive antenna according to the aspect of the invention which generates the terahertz wave by irradiation with the light pulse.

Since such a terahertz wave generation device includes the photoconductive antenna, it is possible to improve an increase in power.

Still another aspect of the invention is directed to a camera including: a light pulse generation device that generates a light pulse; the photoconductive antenna according to the aspect of the invention that generates the terahertz wave by irradiation with the light pulse; a terahertz wave detection portion that detects the terahertz wave emitted from the photoconductive antenna and passing through an object or the terahertz wave reflected from the object; and a storage portion that stores detection results of the terahertz wave detection portion.

In such a camera, since the photoconductive antenna according to the above aspects is included, it is possible to have high detection sensitivity.

Yet another aspect of the invention is directed to an imaging device including: a light pulse generation device that generates a light pulse; the photoconductive antenna according to the aspect of the invention that generates the terahertz wave by irradiation with the light pulse; a terahertz wave detection portion that detects the terahertz wave emitted from the photoconductive antenna and passing through an object or the terahertz wave reflected from the object; and an image forming portion that generates an image of the object on the basis of detection results of the terahertz wave detection portion.

In such an imaging device, since the photoconductive antenna according to the above aspects is included, it is possible to have high detection sensitivity.

Still yet another aspect of the invention is directed to a measurement device including: a light pulse generation device that generates a light pulse; the photoconductive antenna according to the aspect of the invention that generates the terahertz wave by irradiation with the light pulse; a terahertz wave detection portion that detects the terahertz wave emitted from the photoconductive antenna and passing through an object or the terahertz wave reflected from the object; and a measurement portion that measures the object on the basis of detection results of the terahertz wave detection portion.

In such a measurement device, since the photoconductive antenna according to the above aspects is included, it is possible to have high detection sensitivity.

### BRIEF DESCRIPTION OF THE DRAWINGS

The invention will be described with reference to the accompanying drawings, wherein like numbers reference like elements.

FIG. 1 is a cross-sectional view schematically illustrating a photoconductive antenna according to a first embodiment.

FIG. 2 is a plan view schematically illustrating the photoconductive antenna according to the first embodiment.

FIG. 3 is a plan view schematically illustrating the photoconductive antenna according to the first embodiment.

FIG. 4 is a diagram illustrating a terahertz wave which is emitted from the photoconductive antenna according to the first embodiment.

FIG. 5 is a diagram illustrating a terahertz wave which is emitted from a photoconductive antenna of the related art.

FIG. 6 is a cross-sectional view schematically illustrating a process of manufacturing the photoconductive antenna according to the first embodiment.

FIG. 7 is a plan view schematically illustrating a photoconductive antenna according to a first modification example of the first embodiment.

FIG. 8 is a cross-sectional view schematically illustrating a photoconductive antenna according to a second modification example of the first embodiment.

FIG. 9 is a cross-sectional view schematically illustrating a photoconductive antenna according to a third modification example of the first embodiment.

FIG. 10 is a cross-sectional view schematically illustrating a photoconductive antenna according to a second embodiment.

FIG. 11 is a plan view schematically illustrating the photoconductive antenna according to the second embodiment.

FIG. 12 is a cross-sectional view schematically illustrating a photoconductive antenna according to a modification example of second embodiment.

FIG. 13 is a diagram illustrating a configuration of a terahertz wave generation device according to a third embodiment.

FIG. 14 is a block diagram illustrating an imaging device according to a fourth embodiment.

FIG. 15 is a plan view schematically illustrating a terahertz wave detection portion of the imaging device according to the fourth embodiment.

FIG. 16 is a graph illustrating a spectrum of an object in a terahertz band.

FIG. 17 is an image diagram illustrating a distribution of substances of the object.

FIG. 18 is a block diagram illustrating a measurement device according to a fifth embodiment.

FIG. 19 is a block diagram illustrating a camera according to a sixth embodiment.

FIG. 20 is a perspective view schematically illustrating the camera according to the sixth embodiment.

### DESCRIPTION OF EXEMPLARY EMBODIMENTS

Hereinafter, preferred embodiments of the invention will be described in detail with reference the accompanying drawings. Meanwhile, the embodiments described below are not unduly limited to the disclosure of the invention described in the appended claims. In addition, all the configurations described below are not necessarily the essential components of the invention.

### 1. First Embodiment

### 1.1. Photoconductive Antenna

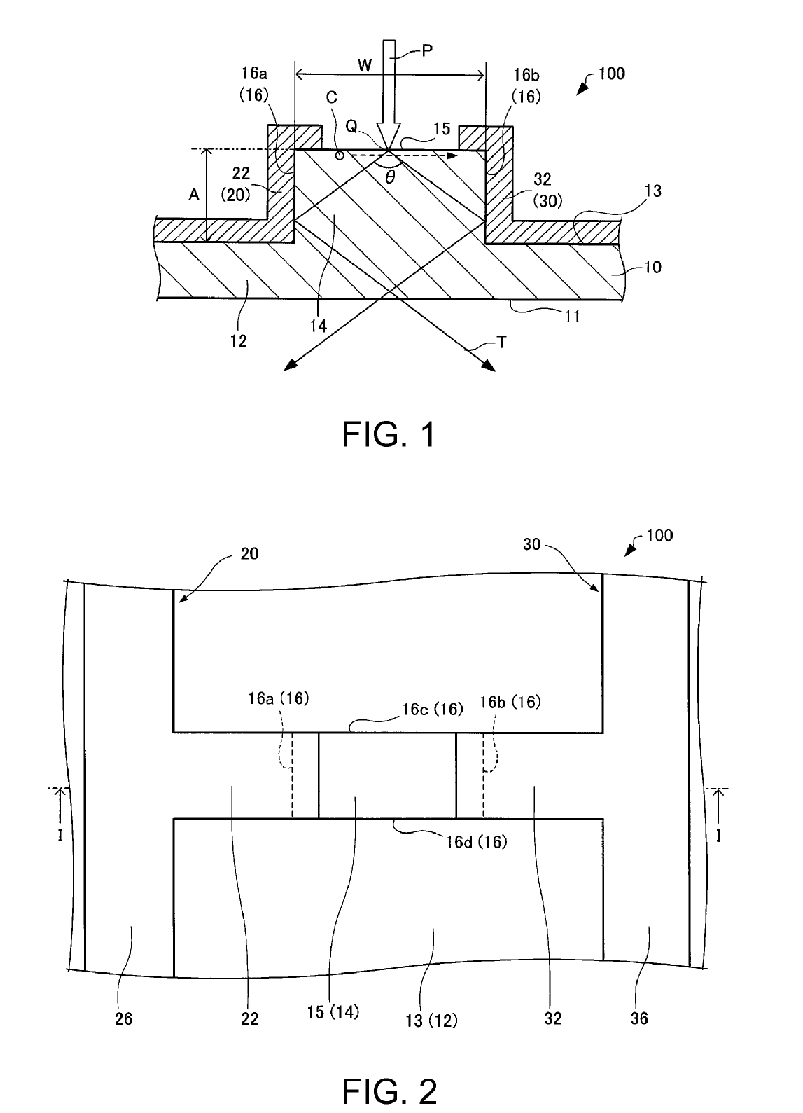

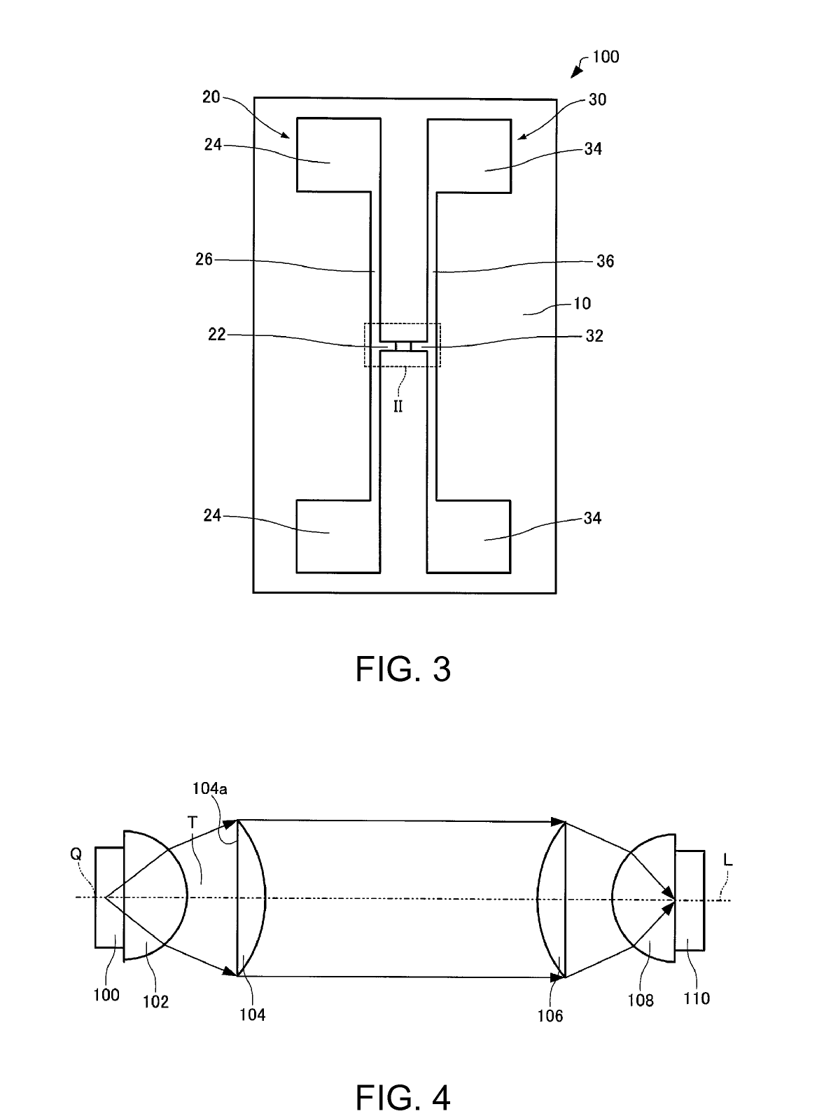

First, a photoconductive antenna according to a first embodiment will be described with reference to the accompanying drawings. FIG. 1 is a cross-sectional view schematically illustrating a photoconductive antenna 100 according to the first embodiment. FIGS. 2 and 3 are plan views schematically illustrating the photoconductive antenna 100 according to the first embodiment. Meanwhile, FIG. 1 is a cross-sectional view taken along line I-I of FIG. 2. In addition, FIG. 2 is an enlarged view of a region II shown in FIG. 3.

As shown in FIGS. 1 to 3, the photoconductive antenna 100 includes a carrier generation layer 10, a first electrode 20, and a second electrode 30. The photoconductive antenna 100 generates a terahertz wave T by irradiation with a light pulse P.

Meanwhile, the term “light pulse” as used herein refers to light of which the intensity changes drastically in a short period of time. The pulse width (full width at half maximum: FWHM) of the light pulse is not particularly limited, but is, for example, equal to or greater than 1 fs (femtosecond) and equal to or less than 800 fs. In addition, the “terahertz wave” refers to an electromagnetic wave having a frequency of equal to or greater than 100 GHz and equal to or less than 30 THz, particularly, an electromagnetic wave having a frequency of equal to or greater than 300 GHz and equal to or less than 3 THz.

The carrier generation layer 10 is constituted by, for example, a semi-insulating substrate. The term “semi-insulating substrate” as used herein refers to a substrate which is constituted by a compound-semiconductor, and a high-resistance (for example, specific resistance is equal to or greater than 10⁷ Ω·cm) substrate. Specifically, the semi-insulating substrate constituting the carrier generation layer 10 is a GaAs substrate which does not contain impurities (which is not doped with impurities). GaAs constituting the carrier generation layer 10 may be in a stoichiometric state. That is, Ga and As constituting the carrier generation layer 10 may be present at a proportion of 1:1. Meanwhile, the semi-insulating substrate constituting the carrier generation layer 10 may be an InP substrate, an InAs substrate, or an InSb substrate.

The carrier generation layer 10 forms carriers C by irradiation with the light pulse P. Specifically, the carrier generation layer 10 forms a plurality of (a large number of) carriers C. When the carrier generation layer 10 is formed of a semi-insulating GaAs substrate, the carrier mobility (electron mobility) of the carrier generation layer 10 is, for example, equal to or greater than 3,000 cm²/Vs and equal to or less than 8,500 cm²/Vs.

Meanwhile, the term “carrier mobility” as used herein refers to a distance which carriers (electrons and holes) transfer per unit hour under a unit electric field intensity when the carriers transfer through a solid-state substance, and a tendency for the carriers to transfer through a solid-state substance.

The carrier generation layer 10 includes a base 12 and a protruding portion 14. The base 12 and the protruding portion 14 are formed integrally. Specifically, the base 12 and the protruding portion 14 can be formed integrally by dry etching a GaAs substrate.

The protruding portion 14 protrudes upward from an upper surface 13 of the base 12. In the example shown in FIG. 1, the protruding portion 14 is interposed between the first electrode 20 and the second electrode 30. In the example shown in FIG. 2, the planar shape of the protruding portion 14 (for example, shape when seen from the vertical direction of the upper surface 13 of the base 12) is rectangular.

The protruding portion 14 has an upper surface 15 and a lateral side 16. In other words, the protruding portion 14 is a portion having a thickness larger than that of a portion excluding the protruding portion 14 of the carrier generation layer 10. The lateral side 16 connects the upper surface 13 of the base 12 and the upper surface 15 of the protruding portion 14. The lateral side 16 is perpendicular to, for example, the upper surface 13 of the base 12. In the shown example, the lateral side 16 is constituted by a first surface 16a provided with the first electrode 20, a second surface 16b provided with the second electrode 30, and a third surface 16c and a fourth surface 16d which are perpendicular to the surfaces 16a and 16b and face each other.

The protruding portion 14 is irradiated with the light pulse P. A portion of the upper surface 15 of the protruding portion 14 may be irradiated with the light pulse P, and the entire upper surface 15 may be irradiated therewith. The protruding portion 14 generates the terahertz wave T by irradiation with the light pulse P.

The lateral side 16 of the protruding portion 14 reflects, at least once, the terahertz wave T which is generated in the protruding portion 14. That is, the protruding portion 14 has such a thickness as to reflect the terahertz wave T at least once at the lateral side 16. Specifically, when the width W of the protruding portion 14 is set to 5 μm, the center of the protruding portion 14 is irradiated with the light pulse P (irradiated with the light pulse P so that the center of the protruding portion 14 and the center of a spot of the light pulse P are coincident with each other when seen in a plan view), and the radiation angle θ of the terahertz wave T is set to 120°, the thickness A of the protruding portion 14 becomes equal to or greater than 1.45 μm.

Meanwhile, when the width W of the protruding portion 14 becomes larger, the minimum value of the thickness A of the protruding portion 14 becomes larger than the above value. In addition, when the radiation angle θ of the terahertz wave T becomes larger, the minimum value of the thickness A of the protruding portion 14 becomes smaller than the above value.

The terahertz wave T which is generated in the protruding portion 14 is reflected from, for example, all the surfaces 16a, 16b, 16c, and 16d constituting the lateral side 16. In the shown example, since the surface 16a is provided with the first electrode 20, and the surface 16b is provided with the second electrode 30, the terahertz wave T is reflected from the surfaces 16a and 16b (from the interface between the surfaces 16a and 16b and the electrodes 20 and 30). The surfaces 16c and 16d are not provided with a metal member such as an electrode, but the refractive index of the protruding portion 14 is larger than the refractive index of the air (for example, the refractive index of GaAs is 3.8), and thus the terahertz wave T is reflected from the surfaces 16c and 16d (from the interface between the surfaces 16c and 16d and the air).

Meanwhile, the terahertz wave T may be reflected from at least any one of the surfaces 16a, 16b, 16c, and 16d. In addition, the numbers of reflections of the terahertz wave T from the surfaces 16a, 16b, 16c, and 16d may be the same as each other, and may be different from each other. The surface from which the terahertz wave T is reflected and the number of reflections are determined by a position which is irradiated with the light pulse P, the planar shape of the protruding portion 14, or the radiation angle θ of the terahertz wave T.

The first electrode 20 and the second electrode 30 are located on the carrier generation layer 10. In the example shown in FIG. 1, the electrodes 20 and 30 are provided on the lateral side 16 of the protruding portion 14, and are further provided on the protruding portion 14. The electrodes 20 and 30 are electrodes that apply a voltage to the carrier generation layer 10. The electrodes 20 and 30 may apply a direct-current (DC) voltage to the carrier generation layer 10, and may apply an alternating-current (AC) voltage thereto. The electrodes 20 and 30 may be brought into ohmic contact with the carrier generation layer 10.

The first electrode 20 and the second electrode 30 are, for example, a Au layer, a Pt layer, a Ti layer, an Al layer, a Cu layer, a Cr layer, or a laminated body thereof. When the laminated body of an Au layer and a Cr layer is used as the electrodes 20 and 30, the Cr layer can improve adhesion between the carrier generation layer 10 and the Au layer.

The first electrode 20 includes a first voltage application portion 22, a first pad portion 24, and a first line portion 26. The second electrode 30 includes a second voltage application portion 32, a second pad portion 34, and a second line portion 36.

The first voltage application portion 22 and the second voltage application portion 32 are portions that apply a voltage to the carrier generation layer 10. In the shown example, the voltage application portions 22 and 32 are located on the protruding portion 14. Specifically, the first voltage application portion 22 is provided on the upper surface 13 of the base 12, the surface 16a of the protruding portion 14, and the upper surface 15 of the protruding portion 14. The second voltage application portion 32 is provided on the upper surface 13 of the base 12, the surface 16b of the protruding portion 14, and the upper surface 15 of the protruding portion 14. A portion of the first voltage application portion 22 and a portion of the second voltage application portion 32 overlap the protruding portion 14 when seen in a plan view (for example, when seen from the vertical direction of the upper surface 13 of the base 12).

A distance between the first voltage application portion 22 and the second voltage application portion 32 is, for example, equal to or greater than 1 μm and equal to or less than 100 μm, and more specifically, is approximately 5 μm. In the shown example, the planar shape of the voltage application portions 22 and 32 is rectangular. That is, the photoconductive antenna 100 is a dipole PCA.

Meanwhile, although not shown in the drawing, the first voltage application portion 22 may have a trapezoidal planar shape having a narrower width toward the second voltage application portion 32 side. Similarly, the second voltage application portion 32 may have a trapezoidal planar shape having a narrower width toward the first voltage application portion 22 side. That is, the photoconductive antenna 100 may be a bow-tie PCA.

The first pad portion 24 and the second pad portion 34 are portions which are connected to an external wiring (not shown). In the shown example, the planar shape of the pad portions 24 and 34 is rectangular. The number of first pad portions 24 provided is, for example, two. The number of second pad portions 34 provided is, for example, two.

The first line portion 26 connects the first voltage application portion 22 and the first pad portion 24. The second line portion 36 connects the second voltage application portion 32 and the second pad portion 34. The line portions 26 and 36 have a belt-like shape when seen in a plan view, and the longitudinal direction of the line portions 26 and 36 is, for example, parallel. The first voltage application portion 22 protrudes from the first line portion 26 in a direction perpendicular to the longitudinal direction of the first line portion 26. The first voltage application portion 22 protrudes from the first line portion 26 to the second electrode 30 side. The second voltage application portion 32 protrudes from the second line portion 36 in a direction perpendicular to the longitudinal direction of the second line portion 36. The second voltage application portion 32 protrudes from the second line portion 36 to the first electrode 20 side.

Next, operations of the photoconductive antenna 100 will be described. In a state where a voltage is applied to the carrier generation layer 10 by the electrodes 20 and 30, the protruding portion 14 located between the electrodes 20 and 30 (between the voltage application portions 22 and 32) when seen in a plan view is irradiated with the light pulse P.

The carriers (for example, electrons) C are instantaneously generated in the protruding portion 14 by irradiation with the light pulse P. The carriers C are accelerated by the voltage applied by the electrodes 20 and 30 and transfer (travel) through the protruding portion 14, and thus a current (photocurrent) flows instantaneously in the protruding portion 14. The terahertz wave T having an intensity proportional to the time variation of the photocurrent is generated. The time variation of the photocurrent is proportional to the carrier mobility of the protruding portion 14. Therefore, the terahertz wave T having an intensity proportional to the carrier mobility of the carrier generation layer 10 is generated in the photoconductive antenna 100.

The light pulse P is mostly absorbed in the vicinity of the upper surface 15, depending on a wavelength, in the depth direction of the protruding portion 14 (direction from the upper surface 15 toward a lower surface 11). For this reason, a rate at which the terahertz wave T is generated in the depth direction of the protruding portion 14 becomes higher in the vicinity of the upper surface 15. Particularly, in the photoconductive antenna 100, since the upper surface 15 of the protruding portion 14 is provided with the electrodes 20 and 30, a distance between the electrodes 20 and 30 is smallest in the upper surface 15 of the protruding portion 14. For this reason, in the photoconductive antenna 100, an electric field intensity in the vicinity of the upper surface 15 becomes largest in the depth direction of the protruding portion 14, and the traveling speed of carriers traveling along the vicinity of the upper surface 15 becomes higher. Meanwhile, the wavelength of the light pulse is, for example, approximately 800 nm.

In the example shown in FIG. 1, the terahertz wave T which is generated in a generation position Q in the vicinity of the upper surface 15 of the protruding portion 14 is once reflected from the lateral side 16 of the protruding portion 14, and then is emitted from the lower surface 11 of the base 12 to the outside of the photoconductive antenna 100.

Meanwhile, in the shown example, the carriers C transfer from the first electrode 20 side toward the second electrode 30 side, but may transfer from the second electrode 30 side toward the first electrode 20 side.

In addition, insofar as the protruding portion 14 is irradiated with the light pulse P, a position or an area which is irradiated with the light pulse P is not particularly limited.

The photoconductive antenna 100 has, for example, the following features.

The photoconductive antenna 100 includes the carrier generation layer 10 that forms the carriers C by irradiation with the light pulse P, and the carrier generation layer 10 includes the protruding portion 14 which is irradiated with the light pulse P. For this reason, the terahertz wave T which is generated in the protruding portion 14 is reflected from the lateral side 16 of the protruding portion 14, and then can be emitted to the outside of the photoconductive antenna 100. Therefore, the terahertz wave T which is generated in the protruding portion 14 is not emanated until the terahertz wave T reaches the lateral side 16 of the protruding portion 14 and then comes out of the protruding portion 14 (reaches the base 12). Thus, in the photoconductive antenna 100, it is possible to reduce an area in which the terahertz wave T is distributed (that is, possible to increase energy density), and to increase the utilization efficiency of light. As a result, it is possible to realize a high-power terahertz wave generation device. Hereinafter, a detailed description will be given.

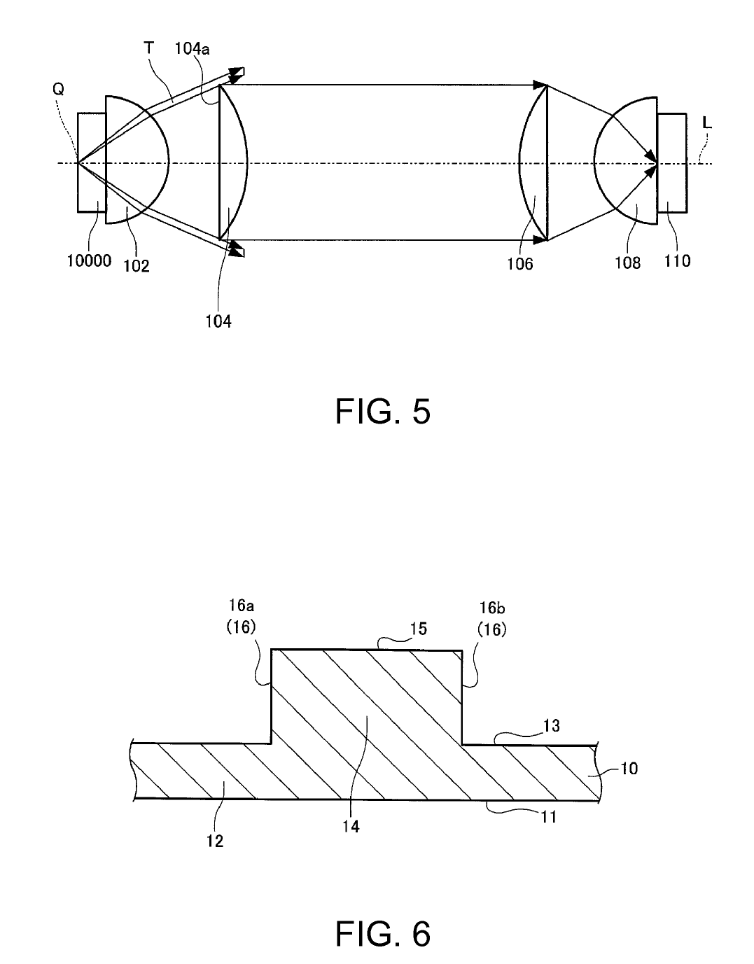

FIG. 4 is a diagram illustrating the terahertz wave T which is emitted from the photoconductive antenna 100. FIG. 5 is a diagram illustrating a terahertz wave T which is emitted from a photoconductive antenna (photoconductive antenna which does not include a protruding portion) 10000 of the related art. Meanwhile, in FIGS. 4 and 5, the photoconductive antennas 100 and 10000 are shown in a simplified manner.

As shown in FIG. 4, the terahertz wave T which is emitted from the photoconductive antenna 100 is detected in a detector 110 through lenses 102, 104, 106, and 108. In the photoconductive antenna 100, the terahertz wave T which is generated in the protruding portion 14 is reflected from the lateral side 16 of the protruding portion 14, and then is emanated and reaches the lens (collimating lens) 104. For this reason, as described above, an area in which the terahertz wave T is distributed (cross-sectional area of the terahertz wave T perpendicular to an optical axis L) can be reduced, and the entirety of the terahertz wave T which is generated in the protruding portion 14 can reach, for example, the lens 104. As a result, the photoconductive antenna 100 can increase the utilization efficiency of light. Further, in the photoconductive antenna 100, it is possible to increase the amount of light capable of being collected in the detector 110.

On the other hand, in the photoconductive antenna 10000 in which the carrier generation layer does not include a protruding portion, for example, the terahertz wave T which is generated in the photoconductive antenna 10000 is emanated from the generation position Q of the terahertz wave T. For this reason, an area in which the terahertz wave T is distributed at a position of an incident surface 104a of the lens 104 becomes larger than in a case of the photoconductive antenna 100. Thereby, as shown in FIG. 5, a portion of the terahertz wave which is emitted from the photoconductive antenna does not reach the lens 104 (does not irradiate the lens 104). For this reason, the utilization efficiency of light may be reduced.

Meanwhile, in the example shown in FIG. 4 and the example shown in FIG. 5, distances between the generation position Q of the terahertz wave T and the lens 102 are the same as each other, and distances between the generation position Q of the terahertz wave T and the lens 104 are the same as each other.

In the photoconductive antenna 100, the first electrode 20 and the second electrode 30 are located above the protruding portion 14. Specifically, the electrodes 20 and 30 are provided on the upper surface 15 of the protruding portion 14. For this reason, in the photoconductive antenna 100, a distance between the electrodes 20 and 30 is smallest in the upper surface 15 of the protruding portion 14. Thereby, in the photoconductive antenna 100, an electric field intensity in the vicinity of the upper surface 15 becomes largest in the depth direction of the protruding portion 14, and the traveling speed of carriers traveling along the vicinity of the upper surface 15 becomes higher. Therefore, in the photoconductive antenna 100, it is possible to generate the terahertz wave T efficiently.

For example, in a configuration in which the electrode is not provided on the upper surface of the protruding portion but is provided on the lateral side of the protruding portion, the terahertz wave T may not be able to be generated efficiently. In such a configuration, a distance between two electrodes is minimized between two lateral sides, and the number of carriers traveling along the vicinity of the upper surface of the protruding portion becomes smaller than that in the aforementioned photoconductive antenna 100. Here, since the protruding portion is formed by, for example, dry etching, a lot of dangling bonds are present on the lateral side of the protruding portion. For this reason, in a configuration in which the electrode is not provided on the upper surface of the protruding portion, carriers are trapped in the dangling bond of the lateral side, and thus the number of carriers which are not capable of traveling may increase. As a result, the terahertz wave may not be able to be generated efficiently.

Further, in the configuration in which the electrode is not provided on the upper surface of the protruding portion but is provided on the lateral side of the protruding portion, a distance (minimum distance) between two electrodes is determined by patterning for forming the protruding portion. Since the thickness of the protruding portion is, for example, larger than the thickness of the electrode, the protruding portion may be difficult to pattern with a high level of accuracy. On the other hand, in the photoconductive antenna 100, since the electrodes 20 and 30 are provided on the upper surface 15 of the protruding portion 14, the distance (minimum distance) between two electrodes 20 and 30 is determined by patterning for forming the electrodes 20 and 30. Since the thickness of the electrodes 20 and 30 is, for example, smaller than the thickness of the protruding portion 14, the electrodes 20 and 30 are able to be patterned with a high level of accuracy. For this reason, in the photoconductive antenna 100, the distance between the electrodes 20 and 30 can be determined with a high level of accuracy.

In the photoconductive antenna 100, the first electrode 20 and the second electrode 30 are provided on the lateral side 16 of the protruding portion 14. For this reason, in the photoconductive antenna 100, the terahertz wave T can be reflected from, for example, the interface between the protruding portion 14 and the first electrode 20, and the interface between the protruding portion 14 and the second electrode 30.

In the photoconductive antenna 100, the carrier generation layer 10 is formed of a semi-insulating substrate. Specifically, the carrier generation layer 10 is formed of a semi-insulating GaAs substrate. For this reason, in the photoconductive antenna 100, the carrier generation layer can have higher carrier mobility than in a case where the layer is formed of an LT-GaAs layer. The intensity of the terahertz wave which is generated in the photoconductive antenna is dependent on the carrier mobility of a layer in which the carriers transfer (travel) in the photoconductive antenna. Therefore, in the photoconductive antenna 100, the intensity of the emitted terahertz wave is made larger, and thus it is possible to achieve an increase in power.

In the photoconductive antenna 100, the carrier generation layer 10 includes the base 12 and the protruding portion 14 protruding upward from the upper surface 13 of the base 12, and the base 12 and the protruding portion 14 are formed integrally. For example, in a configuration in which the base and the protruding portion are formed by separate members (separate layers), the terahertz wave is reflected from the interface between the base and the protruding portion, and thus there may occur a problem in that the intensity of the terahertz wave decreases. In the photoconductive antenna 100, it is possible to avoid such a problem.

### 1.2. Method of Manufacturing Photoconductive Antenna

Next, a method of manufacturing the photoconductive antenna 100 according to the first embodiment will be described with reference to the accompanying drawings. FIG. 6 is a cross-sectional view schematically illustrating a process of manufacturing the photoconductive antenna 100 according to the first embodiment, and corresponds to FIG. 1.

As shown in FIG. 6, a GaAs substrate (not shown) is patterned, and the carrier generation layer 10 including the base 12 and the protruding portion 14 is formed. The base 12 and the protruding portion 14 are formed integrally. The patterning is performed by, for example, photolithography and dry etching.

As shown in FIG. 1, the first electrode 20 and the second electrode 30 are formed on the carrier generation layer 10. The electrodes 20 and 30 are formed by, for example, a combination of a vacuum vapor deposition method and a lift-off method, or the like.

The photoconductive antenna 100 can be manufactured by the above processes.

### 1.3. Modification Example of Photoconductive Antenna

### 1.3.1. First Modification Example

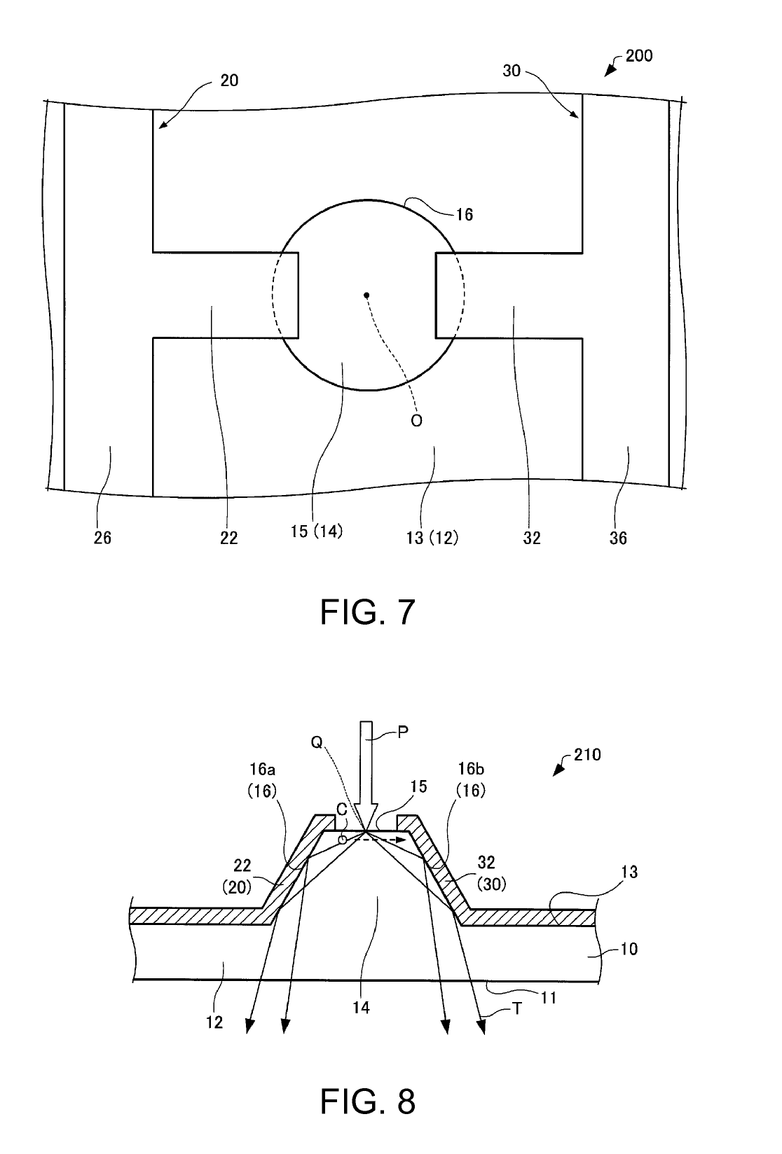

Next, a photoconductive antenna according to a first modification example of the first embodiment will be described with reference to the accompanying drawings. FIG. 7 is a plan view schematically illustrating a photoconductive antenna 200 according to the first modification example of first embodiment. Hereinafter, in the photoconductive antenna 200, members having the same functions as those of the configuration members of the aforementioned photoconductive antenna 100 are assigned the same reference numerals and signs, and thus the detailed description thereof will be omitted.

In the aforementioned photoconductive antenna 100, as shown in FIG. 2, the planar shape of the protruding portion 14 is rectangular. On the other hand, in the photoconductive antenna 200, as shown in FIG. 7, the planar shape of the protruding portion 14 is circular.

In the photoconductive antenna 200, when irradiation with the light pulse P is performed so that the center of a spot of the light pulse P is located at a center O of the protruding portion 14 when seen in a plan view, the cross-sectional shape of the terahertz wave T which is emitted from the photoconductive antenna 200 can be formed to be circular. Thereby, it is possible to facilitate a design of a post-stage optical system (lens).

### 1.3.2. Second Modification Example

Next, a photoconductive antenna according to a second modification example of the first embodiment will be described with reference to the accompanying drawings. FIG. 8 is a cross-sectional view schematically illustrating a photoconductive antenna 210 according to the first modification example of first embodiment, and corresponds to FIG. 1. Hereinafter, in the photoconductive antenna 210, members having the same functions as those of the configuration members of the aforementioned photoconductive antenna 100 are assigned the same reference numerals and signs, and thus the detailed description thereof will be omitted.

In the aforementioned photoconductive antenna 100, as shown in FIG. 1, the lateral side 16 of the protruding portion 14 is perpendicular to the upper surface 13 of the base 12. On the other hand, in the photoconductive antenna 210, as shown in FIG. 8, the lateral side 16 of the protruding portion 14 is inclined with respect to the normal direction of the upper surface 13 of the base 12. In the shown example, the lateral side 16 is inclined with respect to the normal direction of the upper surface 13 so that the width of the protruding portion 14 becomes larger from the upper surface 15 toward the lower surface 11. In other words, the protruding portion 14 is taper-shaped.

In the photoconductive antenna 210, the taper-shaped protruding portion 14 can be formed, for example, by etching a GaAs substrate using a taper-shaped resist as a mask.

In the photoconductive antenna 210, when the thickness of the protruding portion 14 is, for example, smaller than that of the protruding portion 14 of the photoconductive antenna 100, it is possible to increase light collection efficiency, and to increase light utilization efficiency. Further, in the photoconductive antenna 210, it is possible to adjust the distribution of the terahertz wave T which is emitted from the photoconductive antenna 210 by changing the angle between the lateral side 16 of the protruding portion 14 and the upper surface 13 of the base 12.

### 1.3.3. Third Modification Example

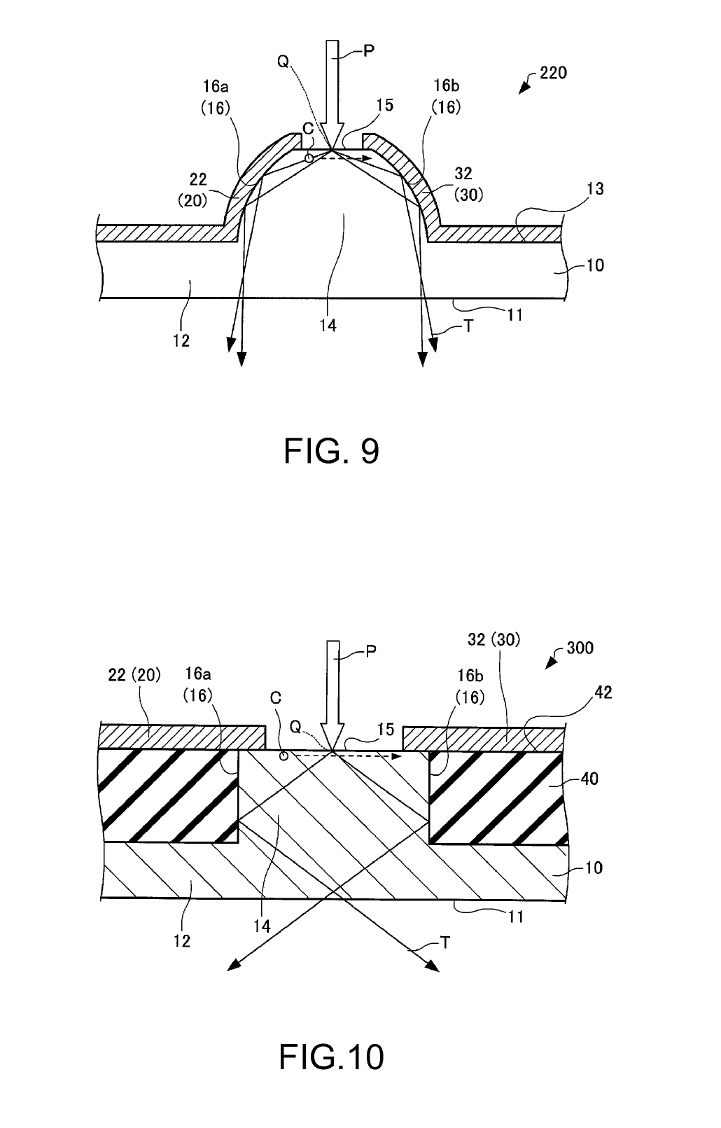

Next, a photoconductive antenna according to a third modification example of the first embodiment will be described with reference to the accompanying drawings. FIG. 9 is a cross-sectional view schematically illustrating a photoconductive antenna 220 according to the third modification example of the first embodiment, and corresponds to FIG. 1. Hereinafter, in the photoconductive antenna 220, members having the same functions as those of the configuration members of the aforementioned photoconductive antenna 100 are assigned the same reference numerals and signs, and thus the detailed description thereof will be omitted.

In the aforementioned photoconductive antenna 100, as shown in FIG. 1, the lateral side 16 of the protruding portion 14 is a flat surface. On the other hand, in the photoconductive antenna 220, as shown in FIG. 9, the lateral side 16 of the protruding portion 14 is a curve. The outer edge of the lateral side 16 (outer edges of the surfaces 16a and 16b) is, for example, a quadratic curve when seen in a cross-sectional view. Meanwhile, although not shown in the drawing, the outer edge of the protruding portion 14 may be parabolic when seen in a cross-sectional view. In addition, although not shown in the drawing, the protruding portion 14 may be spindle-shaped.

In the photoconductive antenna 220, it is possible to form the protruding portion 14 having the lateral side 16 which is a curve, for example, by using proximity exposure.

In the photoconductive antenna 220, it is possible to further improve light collection efficiency than in, for example, the photoconductive antenna 100, and to increase light utilization efficiency. Further, in the photoconductive antenna 220, it is possible to adjust the distribution of the terahertz wave T which is emitted from the photoconductive antenna 220 by changing the curvature of the lateral side 16 which is a curve.

### 2. Second Embodiment

### 2.1. Photoconductive Antenna

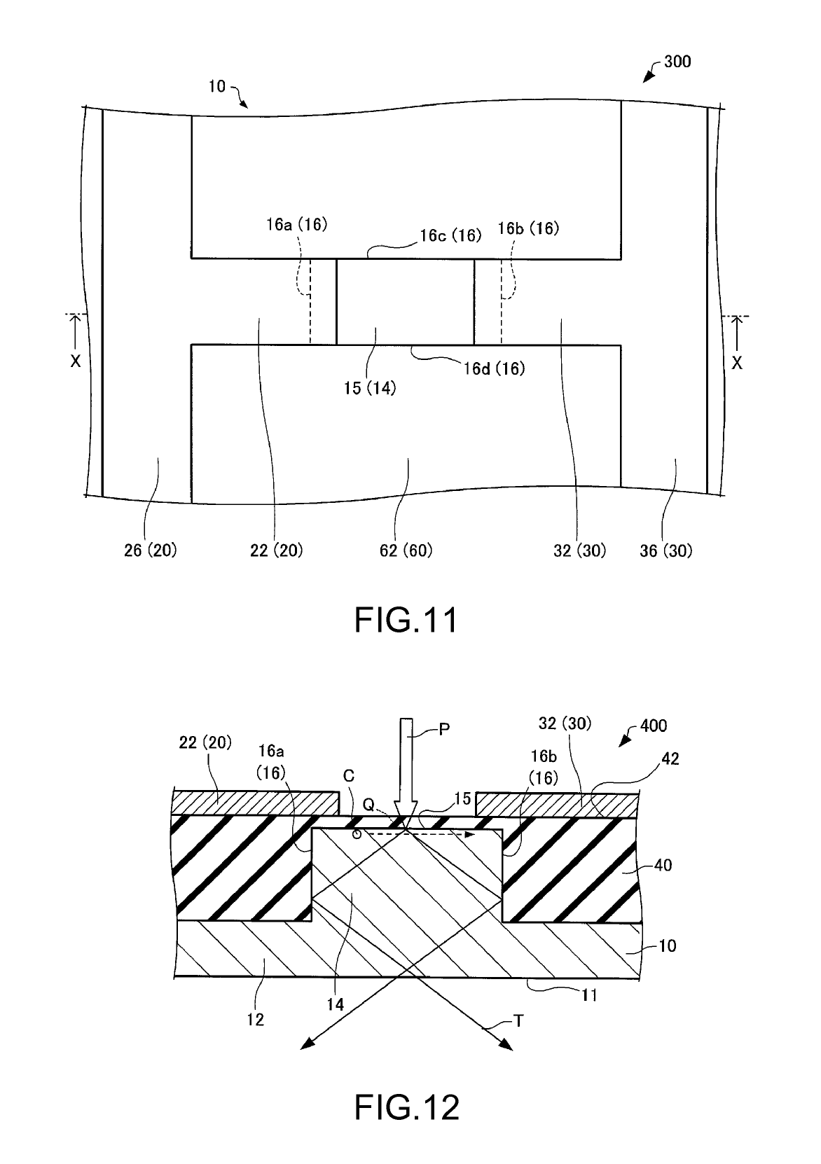

Next, a photoconductive antenna according to a second embodiment will be described with reference to the accompanying drawings. FIG. 10 is a cross-sectional view schematically illustrating a photoconductive antenna 300 according to the second embodiment. FIG. 11 is a plan view schematically illustrating a photoconductive antenna 300 according to the second embodiment. Meanwhile, FIG. 10 is a cross-sectional view taken along line X-X of FIG. 11. Hereinafter, in the photoconductive antenna 300, members having the same functions as those of the configuration members of the aforementioned photoconductive antenna 100 are assigned the same reference numerals and signs, and thus the detailed description thereof will be omitted.

In the aforementioned photoconductive antenna 100, as shown in FIGS. 1 and 2, the lateral side 16 of the protruding portion 14 is provided with the electrodes 20 and 30. On the other hand as shown in FIGS. 10 and 11, the photoconductive antenna 300 includes an insulating layer 40 which is provided on the lateral side 16 of the protruding portion 14.

The insulating layer 40 is provided on the carrier generation layer 10. In the example shown in FIG. 11, the insulating layer 40 is provided so as to surround the protruding portion 14. Specifically, the insulating layer 40 comes into contact with the surfaces 16a, 16b, 16c, and 16d of the protruding portion 14. The electrodes 20 and 30 are provided on the insulating layer 40.

Meanwhile, the insulating layer 40 may not surround the protruding portion 14 when seen in a plan view. That is, the insulating layer 40 may be provided so as to be separated from the surfaces 16c and 16d of the protruding portion 14.

An upper surface 42 of the insulating layer 40 is flush with, for example, the upper surface 15 of the protruding portion 14. The electrodes 20 and 30 are provided on the protruding portion 14 and on the insulating layer 40.

The insulating layer 40 is, for example, an SiO₂ layer and an SiN layer. The refractive index of the insulating layer 40 is smaller than the refractive index of the protruding portion 14. Thereby, it is possible to reflect the terahertz wave T from the lateral side 16 of the protruding portion 14 (from the interface between the lateral side 16 and the insulating layer 40). For example, the refractive index of the insulating layer 40 which is formed of an SiO₂ layer is 1.4.

The photoconductive antenna 300 includes the insulating layer 40 which is provided on the lateral side 16 of the protruding portion 14. For this reason, the electrodes 20 and 30 can be formed in a shape which has no stepped difference or a small stepped difference. Thereby, in the photoconductive antenna 300, it is possible to prevent the electrodes 20 and 30 from being disconnected from each other. As a result, the photoconductive antenna 300 has high reliability, and can improve a yield rate.

Meanwhile, although not shown in the drawing, the photoconductive antenna 200 and the photoconductive antenna 300 may be combined with each other. That is, the insulating layer 40 may be provided on the lateral side 16 of the protruding portion 14 having a circular planar shape.

### 2.2. Method of Manufacturing Photoconductive Antenna

Next, a method of manufacturing the photoconductive antenna 300 according to the second embodiment will be described with reference to the accompanying drawings.

In the method of manufacturing the photoconductive antenna 300, as shown in FIG. 11, the carrier generation layer 10 including the base 12 and the protruding portion 14 is formed, and then the insulating layer 40 is formed on the lateral side of the protruding portion 14. Specifically, first, an insulating layer (not shown) is formed above the carrier generation layer 10 (inclusive of the upper portion of the protruding portion 14) using a CVD (Chemical Vapor Deposition) method, an application method, or the like. Next, the insulating layer is etched, and the upper surface 15 of the protruding portion 14 is exposed. The insulating layer 40 can be formed by the above processes.

Besides the above, the method of manufacturing the photoconductive antenna 300 is substantially the same as the method of manufacturing the photoconductive antenna 100 mentioned above. Thus, the detailed description thereof will be omitted.

### 2.3. Modification Example of Photoconductive Antenna

Next, a photoconductive antenna according to a modification example of the second embodiment will be described with reference to the accompanying drawings. FIG. 12 is a cross-sectional view schematically illustrating a photoconductive antenna 400 according to the modification example of the second embodiment. Hereinafter, in the photoconductive antenna 400, members having the same functions as those of the configuration members of the aforementioned photoconductive antennas 100 and 300 are assigned the same reference numerals and signs, and thus the detailed description thereof will be omitted.

In the aforementioned photoconductive antenna 300, the upper surface 15 of the protruding portion 14 is exposed. On the other hand, in the photoconductive antenna 400, as shown in FIG. 12, the upper surface 15 of the protruding portion 14 is provided with the insulating layer 40.

The thickness of the insulating layer 40 on the protruding portion 14 is of such an extent that a voltage can be applied to the protruding portion 14 by the electrodes 20 and 30. The light pulse P can pass through the insulating layer 40. The electrodes 20 and 30 are provided on the insulating layer 40.

In a method of manufacturing the photoconductive antenna 400, an insulating layer (not shown) is formed above the carrier generation layer 10 (inclusive of the upper portion of the protruding portion 14), and then the insulating layer for exposing the upper surface 15 of the protruding portion 14 is not etched.

Besides the above, the method of manufacturing the photoconductive antenna 400 is substantially the same as the method of manufacturing the photoconductive antenna 300 mentioned above. Thus, the detailed description thereof will be omitted.

In the photoconductive antenna 400, the insulating layer 40 is provided on the upper surface 15 of the protruding portion 14. Therefore, in the photoconductive antenna 400, it is possible to suppress the flow of a leakage current between the electrodes 20 and 30, and to improve a breakdown voltage. As a result, the photoconductive antenna 400 has high reliability, and can improve a yield rate. Further, it is possible to reduce power consumption.

Meanwhile, although not shown in the drawing, the photoconductive antenna 200 and the photoconductive antenna 400 may be combined with each other. That is, the insulating layer 40 may be provided on the upper surface 15 and the lateral side 16 of the protruding portion 14 having a circular planar shape.

### 3. Third Embodiment

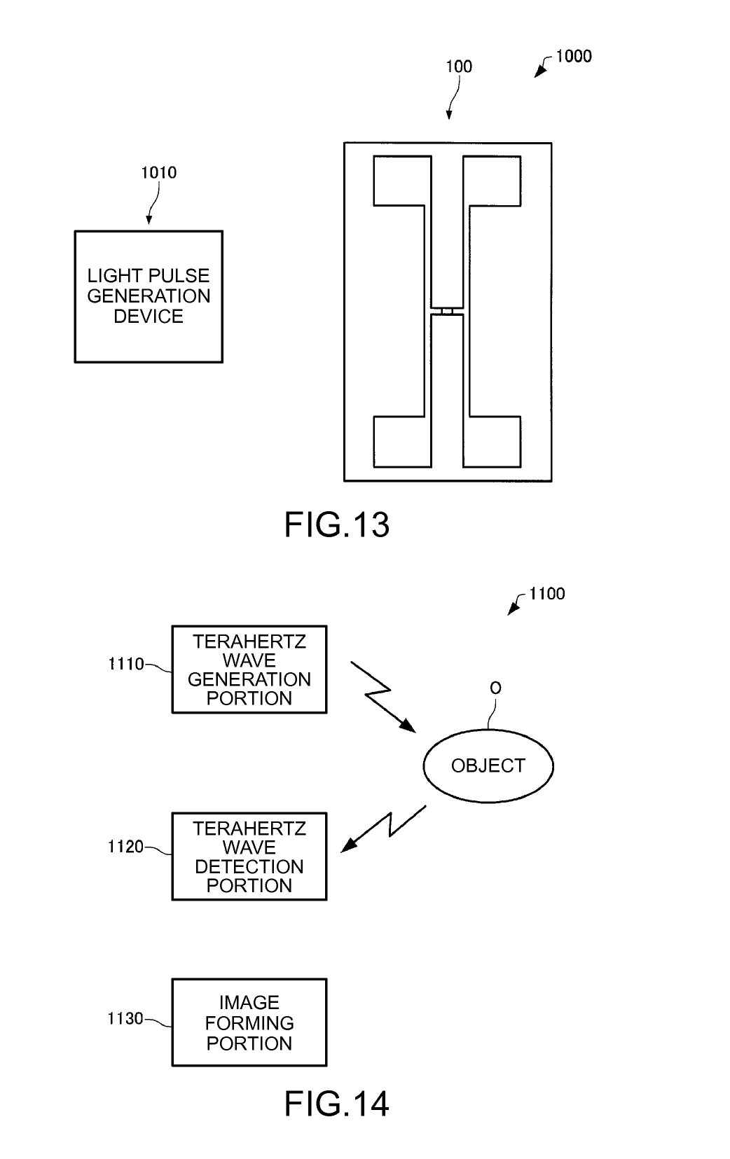

Next, a terahertz wave generation device 1000 according to a third embodiment will be described with reference to the accompanying drawings. FIG. 13 is a diagram illustrating a configuration of the terahertz wave generation device 1000 according to the third embodiment.

As shown in FIG. 13, the terahertz wave generation device 1000 includes a light pulse generation device 1010 and the photoconductive antenna according to the invention. Hereinafter, an example will be described in which the photoconductive antenna 100 is used as the photoconductive antenna according to the invention.

The light pulse generation device 1010 generates a light pulse (for example, light pulse P shown in FIG. 1) which is excitation light. The light pulse generation device 1010 irradiates the photoconductive antenna 100. The width of the light pulse which is generated by the light pulse generation device 1010 is, for example, equal to or greater than 1 fs and equal to or less than 800 fs. As the light pulse generation device 1010, for example, a femtosecond fiber laser or a titanium sapphire laser is used.

As described above, the photoconductive antenna 100 can generate a terahertz wave by irradiation with a light pulse.

The terahertz wave generation device 1000 includes the photoconductive antenna 100, and thus can improve an increase in power.

### 4. Fourth Embodiment

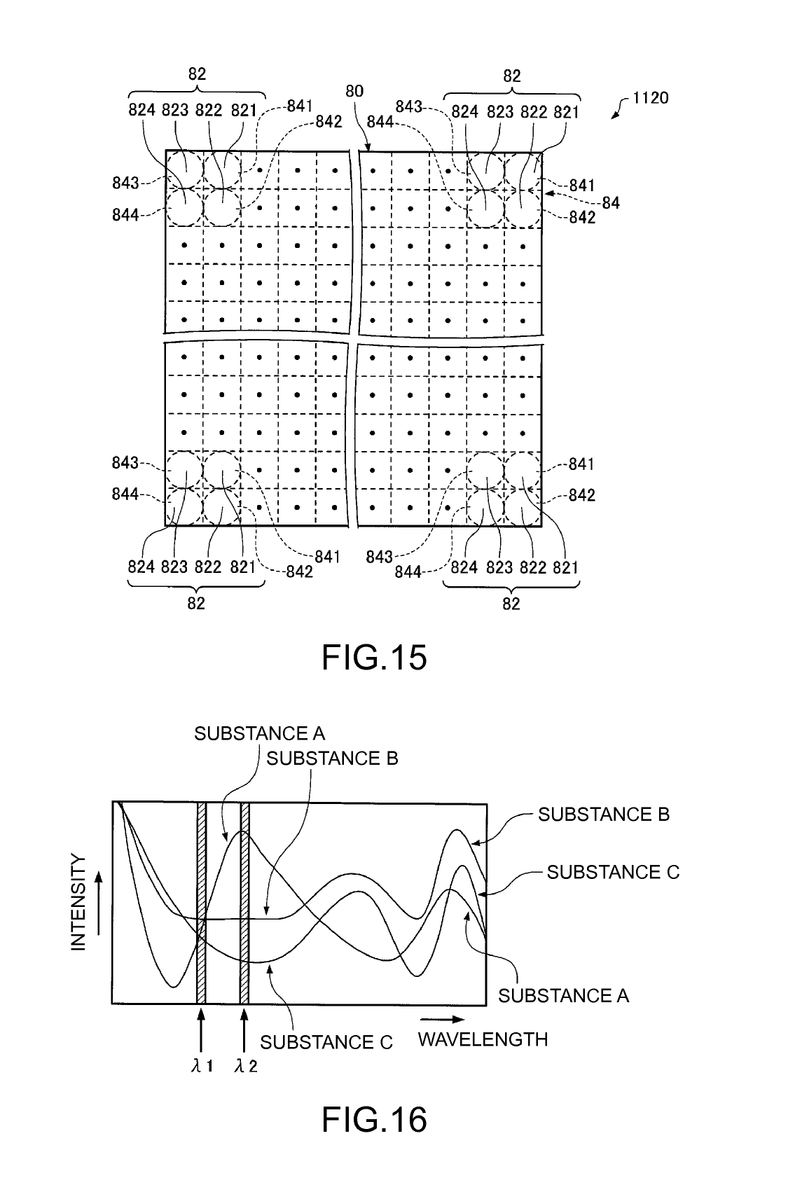

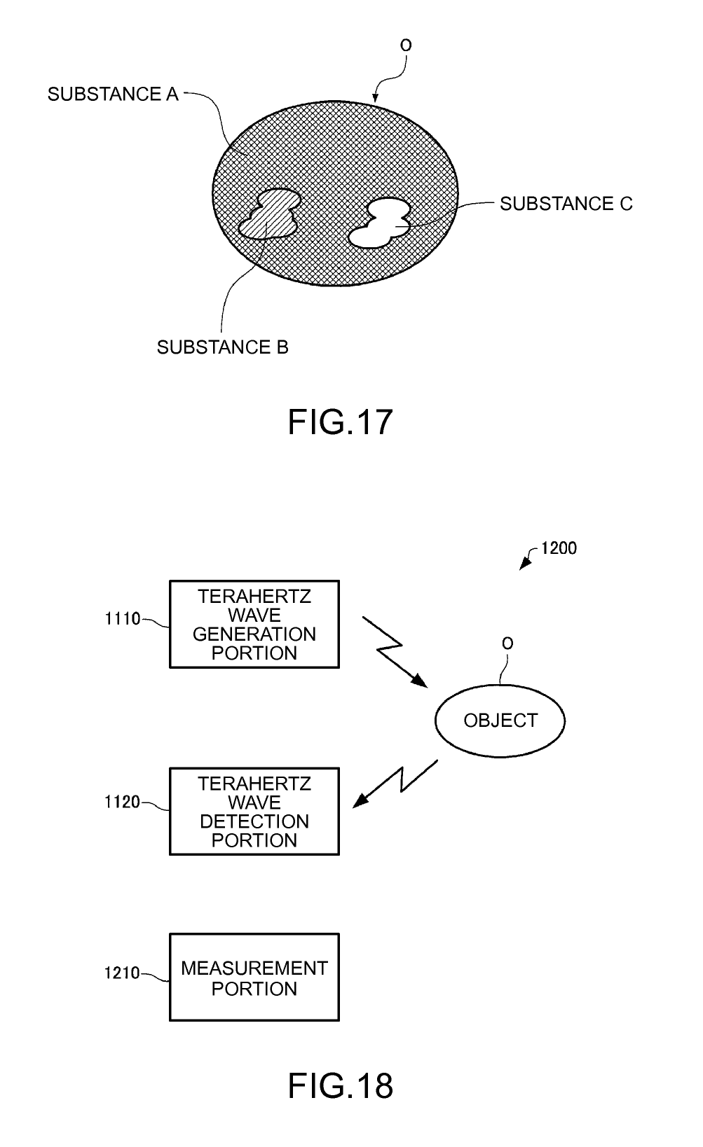

Next, an imaging device 1100 according to a fourth embodiment will be described with reference to the accompanying drawings. FIG. 14 is a block diagram illustrating the imaging device 1100 according to the fourth embodiment. FIG. 15 is a plan view schematically illustrating a terahertz wave detection portion 1120 of the imaging device 1100 according to the fourth embodiment. FIG. 16 is a graph illustrating a spectrum of an object in a terahertz band. FIG. 17 is an image diagram illustrating a distribution of substances A, B and C of the object.

As shown in FIG. 14, the imaging device 1100 includes a terahertz wave generation portion 1110 that generates a terahertz wave, a terahertz wave detection portion 1120 that detects a terahertz wave emitted from the terahertz wave generation portion 1110 and passing through an object O or a terahertz wave reflected from the object O, and an image forming portion 1130 that generates an image of the object O, that is, image data on the basis of a detection result of the terahertz wave detection portion 1120.

As the terahertz wave generation portion 1110, a terahertz wave generation device according to the invention can be used. Here, a case will be described in which the terahertz wave generation device 1000 is used as the terahertz wave generation device according to the invention.

The terahertz wave detection portion 1120 to be used includes a filter 80 that transmits a terahertz wave having an objective wavelength and a detection portion 84 that detects the terahertz wave having an objective wavelength having passed through the filter 80, as shown in FIG. 15. In addition, the detection portion 84 to be used has, for example, a function of converting a terahertz wave into heat to detect the converted terahertz wave, that is, a function capable of converting a terahertz wave into heat to detect energy (intensity) of the terahertz wave. Such a detection portion includes, for example, a pyroelectric sensor, a bolometer or the like. Meanwhile, the configuration of the terahertz wave detection portion 1120 is not limited to the above-mentioned configuration.

In addition, the filter 80 includes a plurality of pixels (unit filter portions) 82 which are arranged two-dimensionally. That is, the respective pixels 82 are arranged in a matrix.

In addition, each of the pixels 82 includes a plurality of regions that transmit terahertz waves having wavelengths different from each other, that is, a plurality of regions in which wavelengths of terahertz waves to be transmitted (hereinafter, referred to as “transmission wavelengths”) are different from each other. Meanwhile, in the shown configuration, each of the pixels 82 includes a first region 821, a second region 822, a third region 823, and a fourth region 824.

In addition, the detection portion 84 includes a first unit detection portion 841, a second unit detection portion 842, a third unit detection portion 843 and a fourth unit detection portion 844 which are respectively provided corresponding to the first region 821, the second region 822, the third region 823 and the fourth region 824 of each pixel 82 of the filter 80. Each first unit detection portion 841, each second unit detection portion 842, each third unit detection portion 843 and each fourth unit detection portion 844 convert terahertz waves which have respectively passed through the first region 821, the second region 822, the third region 823 and the fourth region 824 of each pixel 82 into heat to detect the converted terahertz waves. Thereby, it is possible to reliably detect the terahertz waves having four objective wavelengths in the respective regions of each pixel 82.

Next, an example of use of the imaging device 1100 will be described.

First, the object O targeted for spectroscopic imaging is constituted by three substances A, B and C. The imaging device 1100 performs spectroscopic imaging on the object O. In addition, here, as an example, the terahertz wave detection portion 1120 is assumed to detect a terahertz wave reflected from the object O.

In addition, the first region 821 and the second region 822 are used in each pixel 82 of the filter 80 of the terahertz wave detection portion 1120. When the transmission wavelength of the first region 821 is set to Xl, the transmission wavelength of the second region 822 is set to λ2, the intensity of a component having the wavelength λ1 of the terahertz wave reflected from the object O is set to al, and the intensity of a component having the wavelength λ2 is set to α2, the transmission wavelength λ1 of the first region 821 and the transmission wavelength λ2 of the second region 822 are set so that differences (α2−α1) between the intensity α2 and the intensity α1 can remarkably distinguish from each other in the substance A, the substance B and the substance C.

As shown in FIG. 16, in the substance A, the difference (α2−α1) between the intensity α2 of the component having the wavelength λ2 of the terahertz wave reflected from the object O and the intensity α1 of the component having the wavelength λ1 is set to a positive value. In addition, in the substance B, the difference (α2−α1) between the intensity α2 and the intensity α1 is set to zero. In addition, in the substance C, the difference (α2−α1) between the intensity α2 and the intensity α1 is set to a negative value.

When the spectroscopic imaging of the object O is performed by the imaging device 1100, a terahertz wave is first generated by the terahertz wave generation portion 1110, and the object O is irradiated with the terahertz wave. The terahertz wave reflected from the object O is then detected as α1 and α2 in the terahertz wave detection portion 1120. The detection results are sent out to the image forming portion 1130. Meanwhile, the irradiation of the object O with the terahertz wave and the detection of the terahertz wave reflected from the object O are performed on the entire object O.

In the image forming portion 1130, the difference (α2−α1) between the intensity α2 of the component having the wavelength λ2 of the terahertz wave having passed through the second region 822 of the filter 80 and the intensity α1 of the component having the wavelength λ1 of the terahertz wave having passed through the first region 821 is obtained on the basis of the above detection results. In the object O, a region in which the difference is set to a positive value is determined to be the substance A, a region in which the difference is set to zero is determined to be the substance B, and a region in which the difference is set to a negative value is determined to be the substance C, and the respective regions are specified.

In addition, in the image forming portion 1130, image data of an image indicating the distribution of the substances A, B and C of the object O is created as shown in FIG. 17. The image data is sent out from the image forming portion 1130 to a monitor which is not shown, and the image indicating the distribution of the substances A, B and C of the object O is displayed on the monitor. In this case, for example, using color coding, the region in which the substance A of the object O is distributed is displayed in a black color, the region in which the substance B is distributed is displayed in an ash color, and the region in which the substance C is distributed is displayed in a white color. In the imaging device 1100, in this manner, the identification of each substance constituting the object O and the distribution measurement of each substance can be simultaneously performed.

Meanwhile, the application of the imaging device 1100 is not limited to the above. For example, a person is irradiated with a terahertz wave, the terahertz wave transmitted or reflected through or from the person is detected, and a process is performed in the image forming portion 1130, and thus it is possible to discriminate whether the person carries a pistol, a knife, an illegal medicinal substance, and the like.

The imaging device 1100 includes the photoconductive antenna 100 which is capable of achieving an increase in power. For this reason, the imaging device 1100 can have high detection sensitivity.

### 5. Fifth Embodiment

Next, a measurement device 1200 according to a fifth embodiment will be described with reference to the accompanying drawings. FIG. 18 is a block diagram illustrating the measurement device 1200 according to the fifth embodiment. In the measurement device 1200 according to the fifth embodiment described below, members having the same functions as those of the configuration members of the aforementioned imaging device 1100 are assigned the same reference numerals and signs, and thus the detailed description thereof will be omitted.

As shown in FIG. 18, the measurement device 1200 includes a terahertz wave generation portion 1110 that generates a terahertz wave, a terahertz wave detection portion 1120 that detects a terahertz wave emitted from the terahertz wave generation portion 1110 and passing through the object O or a terahertz wave reflected from the object O, and a measurement portion 1210 that measures the object O on the basis of a detection result of the terahertz wave detection portion 1120.

Next, an example of use of the measurement device 1200 will be described. When the spectroscopic measurement of the object O is performed by the measurement device 1200, a terahertz wave is first generated by the terahertz wave generation portion 1110, and the object O is irradiated with the terahertz wave. The terahertz wave having passed through the object O or a terahertz wave reflected from the object O is then detected in the terahertz wave detection portion 1120. The detection results are sent out to the measurement portion 1210. Meanwhile, the irradiation of the object O with the terahertz wave and the detection of the terahertz wave having passed through the object O or the terahertz wave reflected from the object O are performed on the entire object O.

In the measurement portion 1210, the intensity of each terahertz wave having passed through the first region 821, the second region 822, the third region 823 and the fourth region 824 of each pixel 82 of the filter 80 is ascertained from the above detection results, and the analysis or the like of components of the object O and the distribution thereof is performed.

The measurement device 1200 includes the photoconductive antenna 100 which is capable of achieving an increase in power. For this reason, the measurement device 1200 can have high detection sensitivity.

### 6. Sixth Embodiment

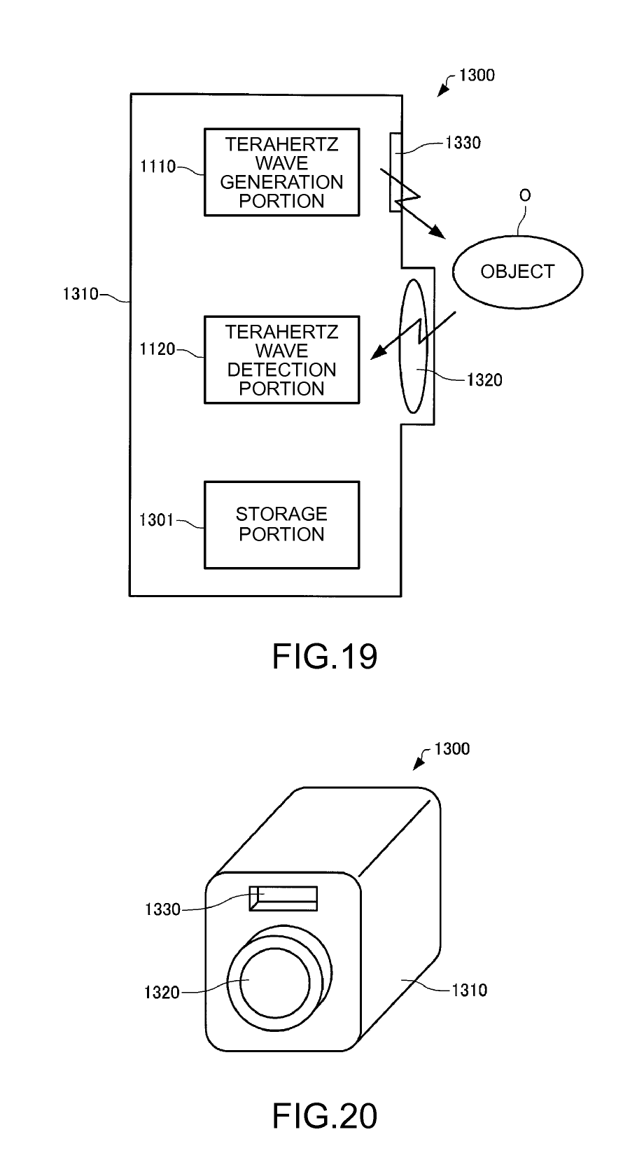

Next, a camera 1300 according to a sixth embodiment will be described with reference to the accompanying drawings. FIG. 19 is a block diagram illustrating the camera 1300 according to the sixth embodiment. FIG. 20 is a perspective view schematically illustrating the camera 1300 according to the sixth embodiment. In the camera 1300 according to the sixth embodiment described below, members having the same functions as those of the configuration members of the aforementioned imaging device 1100 are assigned the same reference numerals and signs, and thus the detailed description thereof will be omitted.

As shown in FIGS. 19 and 20, the camera 1300 includes a terahertz wave generation portion 1110 that generates a terahertz wave, a terahertz wave detection portion 1120 that detects a terahertz wave emitted from the terahertz wave generation portion 1110 and passing through the object O or a terahertz wave reflected from the object O, and a storage portion 1301. The respective portions 1110, 1120, and 1301 are contained in a housing 1310 of the camera 1300. In addition, the camera 1300 includes a lens (optical system) 1320 that converges (images) the terahertz wave reflected from the object O onto the terahertz wave detection portion 1120, and a window 1330 that emits the terahertz wave generated in the terahertz wave generation portion 1110 to the outside of the housing 1310. The lens 1320 and the window 1330 are constituted by members, such as silicon, quartz, or polyethylene, which transmit and refract the terahertz wave. Meanwhile, the window 1330 may have a configuration in which an opening is simply provided as in a slit.

Next, an example of use of the camera 1300 will be described. When the object O is imaged by the camera 1300, a terahertz wave is first generated by the terahertz wave generation portion 1110, and the object O is irradiated with the terahertz wave. The terahertz wave reflected from the object O is converged (imaged) onto the terahertz wave detection portion 1120 by the lens 1320 to detect the converged wave. The detection results are sent out to the storage portion 1301 and are stored therein. Meanwhile, the irradiation of the object O with the terahertz wave and the detection of the terahertz wave reflected from the object O are performed on the entire object O. In addition, the above detection results can also be transmitted to, for example, an external device such as a personal computer. In the personal computer, each process can be performed on the basis of the above detection results.

The camera 1300 includes the photoconductive antenna 100 which is capable of achieving an increase in power. For this reason, the camera 1300 can have high detection sensitivity.

The above-mentioned embodiments and modification examples are illustrative examples, and are not limited thereto. For example, each of the embodiments and each of the modification examples can also be appropriately combined.

The invention includes substantially the same configurations (for example, configurations having the same functions, methods and results, or configurations having the same objects and effects) as the configurations described in the embodiments. In addition, the invention includes a configuration obtained by replacing non-essential portions in the configurations described in the embodiments. In addition, the invention includes a configuration that exhibits the same operations and effects as those of the configurations described in the embodiment or a configuration capable of achieving the same objects. In addition, the invention includes a configuration obtained by adding the configurations described in the embodiments to general techniques.

The entire disclosure of Japanese Patent Application No. 2014-022242, filed Feb. 7, 2014 is expressly incorporated by reference herein.

What is claimed is:

1. A photoconductive antenna that generates a terahertz wave by irradiation with a light pulse, comprising:
a carrier generation layer that has carriers formed therein by irradiation with the light pulse; and
a first electrode and a second electrode, located above the carrier generation layer, which apply a voltage to the carrier generation layer,
wherein the carrier generation layer includes a protruding portion which is irradiated with the light pulse.

2. The photoconductive antenna according to claim 1, wherein the first electrode and the second electrode are located above the protruding portion.

3. The photoconductive antenna according to claim 2, wherein the first electrode and the second electrode are provided on a lateral side of the protruding portion.

4. The photoconductive antenna according to claim 2, further comprising an insulating layer which is provided on the lateral side of the protruding portion.

5. The photoconductive antenna according to claim 4, wherein the insulating layer is provided on an upper surface of the protruding portion.

6. The photoconductive antenna according to claim 1, wherein a planar shape of the protruding portion is circular.

7. The photoconductive antenna according to claim 1, wherein the carrier generation layer is formed of a semi-insulating layer substrate.

8. A terahertz wave generation device comprising:
a light pulse generation device that generates a light pulse; and
the photoconductive antenna according to claim 1 which generates the terahertz wave by irradiation with the light pulse.

9. A terahertz wave generation device comprising:
a light pulse generation device that generates a light pulse; and
the photoconductive antenna according to claim 2 which generates the terahertz wave by irradiation with the light pulse.

10. A terahertz wave generation device comprising:
a light pulse generation device that generates a light pulse; and
the photoconductive antenna according to claim 3 which generates the terahertz wave by irradiation with the light pulse.

11. A terahertz wave generation device comprising:
a light pulse generation device that generates a light pulse; and
the photoconductive antenna according to claim 4 which generates the terahertz wave by irradiation with the light pulse.

12. A camera comprising:
a light pulse generation device that generates a light pulse;
the photoconductive antenna according to claim 1 that generates the terahertz wave by irradiation with the light pulse;
a terahertz wave detection portion that detects the terahertz wave emitted from the photoconductive antenna and passing through an object or the terahertz wave reflected from the object; and
a storage portion that stores detection results of the terahertz wave detection portion.

13. A camera comprising:
a light pulse generation device that generates a light pulse;
the photoconductive antenna according to claim 2 that generates the terahertz wave by irradiation with the light pulse;
a terahertz wave detection portion that detects the terahertz wave emitted from the photoconductive antenna and passing through an object or the terahertz wave reflected from the object; and
a storage portion that stores detection results of the terahertz wave detection portion.

14. A camera comprising:
a light pulse generation device that generates a light pulse;
the photoconductive antenna according to claim 3 that generates the terahertz wave by irradiation with the light pulse;
a terahertz wave detection portion that detects the terahertz wave emitted from the photoconductive antenna and passing through an object or the terahertz wave reflected from the object; and
a storage portion that stores detection results of the terahertz wave detection portion.

15. An imaging device comprising:
a light pulse generation device that generates a light pulse;
the photoconductive antenna according to claim 1 that generates the terahertz wave by irradiation with the light pulse;
a terahertz wave detection portion that detects the terahertz wave emitted from the photoconductive antenna and passing through an object or the terahertz wave reflected from the object; and
an image forming portion that generates an image of the object on the basis of detection results of the terahertz wave detection portion.

16. An imaging device comprising:
a light pulse generation device that generates a light pulse;
the photoconductive antenna according to claim 2 that generates the terahertz wave by irradiation with the light pulse;
a terahertz wave detection portion that detects the terahertz wave emitted from the photoconductive antenna and passing through an object or the terahertz wave reflected from the object; and
an image forming portion that generates an image of the object on the basis of detection results of the terahertz wave detection portion.

17. An imaging device comprising:
a light pulse generation device that generates a light pulse;
the photoconductive antenna according to claim 3 that generates the terahertz wave by irradiation with the light pulse;
a terahertz wave detection portion that detects the terahertz wave emitted from the photoconductive antenna and passing through an object or the terahertz wave reflected from the object; and
an image forming portion that generates an image of the object on the basis of detection results of the terahertz wave detection portion.

18. A measurement device comprising:
a light pulse generation device that generates a light pulse;
the photoconductive antenna according to claim 1 that generates the terahertz wave by irradiation with the light pulse;
a terahertz wave detection portion that detects the terahertz wave emitted from the photoconductive antenna and passing through an object or the terahertz wave reflected from the object; and
a measurement portion that measures the object on the basis of detection results of the terahertz wave detection portion.

19. A measurement device comprising:
a light pulse generation device that generates a light pulse;
the photoconductive antenna according to claim 2 that generates the terahertz wave by irradiation with the light pulse;
a terahertz wave detection portion that detects the terahertz wave emitted from the photoconductive antenna and passing through an object or the terahertz wave reflected from the object; and
a measurement portion that measures the object on the basis of detection results of the terahertz wave detection portion.

20. A measurement device comprising:
a light pulse generation device that generates a light pulse;
the photoconductive antenna according to claim 3 that generates the terahertz wave by irradiation with the light pulse;
a terahertz wave detection portion that detects the terahertz wave emitted from the photoconductive antenna and passing through an object or the terahertz wave reflected from the object; and
a measurement portion that measures the object on the basis of detection results of the terahertz wave detection portion.
